(19) United States
(12) Patent Application Publication
(10) Pub. No.: US 2026/0128571 A1
(43) Pub. Date: May 7, 2026

(54) MULTIPLE QUANTUM WELL STRUCTURE, SEMICONDUCTOR LASER AND MANUFACTURING METHOD FOR MULTIPLE QUANTUM WELL STRUCTURE

(71) Applicant: Nippon Telegraph and Telephone Corporation, Tokyo (JP)

(72) Inventors: Manabu Mitsuhara, Tokyo (JP); Wataru Kobayashi, Tokyo (JP); Takahiko Shindo, Tokyo (JP)

(21) Appl. No.: 19/129,172

(22) PCT Filed: Nov. 14, 2022
(86) PCT No.: PCT/JP2022/042211

§ 371 Date: May 12, 2025

(51) Int. Cl. H01S 5/343; H01S 5/34

(52) U.S. Cl. CPC H01S 5/34386; H01S 5/3407

(57) ABSTRACT

An embodiment is a multiple quantum well structure between a p-type semiconductor and an n-type semiconductor in a semiconductor laser, the multiple quantum well structure including a plurality of well layers, and a plurality of barrier layers having shorter composition wavelengths than the plurality of well layers, where at least one of the plurality of well layers, excluding a p-side well layer closest to the p-type semiconductor, has a quantum level wavelength shorter than a quantum level wavelength of the p-side well layer.

### CROSS-REFERENCE TO RELATED APPLICATIONS

This application is a national phase entry of PCT Application No. PCT/JP2022/042211, filed on Nov. 14, 2022, which application is hereby incorporated herein by reference.

### TECHNICAL FIELD

The present disclosure relates to a multiple quantum well structure.

### BACKGROUND

In recent years, with the rapid development of services requiring large-capacity data communication, such as κG and cloud services, semiconductor lasers have been used not only for long-distance optical communication but also for short-distance optical communication in access networks or data centers. In addition, semiconductor lasers are also used as light sources for gas sensing. In gas sensing, various gases absorb light of specific wavelengths (absorption lines), and thus, by analyzing a change in light intensity when laser light is passed through a gas, a concentration of the gas and a local distribution thereof are measured in real time.

A basic condition for oscillating semiconductor laser is that a gain of an active layer is greater than a loss. For this reason, in a semiconductor whose cleavage plane serves as a mirror of a resonator laser (hereinafter referred to as “Fabry-Perot laser”), a laser oscillation wavelength is near a peak wavelength of a gain of an active layer.

On the other hand, an oscillation wavelength of a distributed feedback laser diode (hereinafter also referred to as “DFB laser”) that oscillates at a single wavelength is mainly determined by a period and a refractive index of a diffraction grating formed near a waveguide such as an upper portion or a lower portion of an active layer. More specifically, when first-order diffracted light is used with a period of a diffraction grating defined as Δ and a refractive index (equivalent refractive index) sensed by light propagating through a laser waveguide defined as n_{eff}, a desired oscillation wavelength λ_{DFB} in a distributed feedback laser diode is given by λ_{DFB}=2Λ×n_{eff}. It is known that an oscillation wavelength of a distributed feedback laser diode changes when an operating temperature changes, but this change in wavelength is less affected by a change in period of a diffraction grating due to thermal expansion and more affected by a change in refractive index with temperature (for example, NPL 1).

As described above, a change in the oscillation wavelength of the Fabry-Perot laser with temperature depends mainly on a change in the peak wavelength of the gain. On the other hand, a change in the oscillation wavelength of the distributed feedback laser diode with temperature depends mainly on a change in the refractive index of the diffraction grating.

Here, in the distributed feedback laser diode, when the oscillation wavelength is set to a wavelength having a small gain of the active layer due to a configuration of the diffraction grating, good laser characteristics (a threshold current, efficiency, and the like) cannot be obtained because of low light emission efficiency. Accordingly, in order to improve characteristics of the distributed feedback laser diode, it is necessary to set the oscillation wavelength to a wavelength having a large gain of the active layer. In this way, it is desirable to perform setting in consideration of a gain of the active layer along with a configuration of the diffraction grating.

As described above, oscillation wavelengths of a Fabry-Perot laser and a distributed feedback (DFB) laser diode change with temperature at different rates (for example, NPL 1). FIG. 10 shows changes in oscillation wavelengths with temperature of a Fabry-Perot laser and a DFB laser. Active layers of the Fabry-Perot laser and the DFB laser are active layers each formed by InGaAsP on an InP substrate. A change rate of the oscillation wavelength with temperature is about 0.4 nm/K in the Fabry-Perot laser, and about 0.1 nm/K in the distribution feedback laser diode.

In setting oscillation wavelengths of a Fabry-Perot laser and a distributed feedback laser diode, change rates of the oscillation wavelengths with temperature are different, and thus, it is necessary to consider a gain of an active layer at an operating temperature. For example, when an oscillation wavelength of a distributed feedback laser diode is set in accordance with a peak of a gain near room temperature, the laser can obtain good laser characteristics near room temperature, but a difference between the set wavelength and the peak of the gain of the semiconductor laser increases as a temperature difference from the room temperature increases due to the change with temperature, and thus the laser characteristics deteriorate.

In order to inhibit the deterioration of the laser characteristics due to the temperature change, in general, when a semiconductor laser such as a distributed feedback laser diode is used under an environment in which an operating temperature fluctuates, the semiconductor laser is operated by installing a temperature adjusting element to keep a temperature of the semiconductor laser constant.

### CITATION LIST

### Non Patent Literature

[NPL 1] K. One et al., “Proposal on a temperature-insensitive wavelength semiconductor laser,” IEICE Trans. Electron, Vol. E79-C, No. 12, 1996, 1751-1759.
[NPL 2] J. Liu et al., “Electrically injected Asabi/GaAs single quantum well laser diodes,” AIP Advance, Vol. 7, No. 12, 2017, 115006.
[NPL 3] A. Inada et al., “Temperature stability of the refractive index and the direct band edge in Lingaa quaternary allows,” Appl. Phys. Lett., Vol. 84, No. 21, 2004, 4212-4214.

### SUMMARY

### Technical Problem

However, power consumption of a temperature adjusting element such as a Peltier element is large, accounting for nearly half of power consumption required for driving a laser. As a result, power consumption of the entire laser module in which a temperature adjusting element is mounted on a semiconductor laser increases, which is problematic.

Thus, in order to reduce power consumption, a semiconductor laser that can inhibit a change in laser characteristics due to a change in temperature without using a temperature adjusting element is needed.

In order to inhibit a change in laser characteristics with temperature, it is necessary to inhibit a change in a difference between a set wavelength of a semiconductor laser and a peak of a gain when a temperature changes. That is, it is necessary to inhibit a change of the peak of the gain when a temperature changes.

FIG. 11 schematically shows a change in gain spectrum with temperature immediately before laser oscillation. In the figure, λ_{g}(T) is a wavelength corresponding to a bandgap of a semiconductor used for an active layer, and when a quantum well structure is used for the active layer, the wavelength corresponds to an energy difference between a ground quantum level on a valence band side of a well layer and a ground quantum level on a conduction band side thereof (hereinafter referred to as a “quantum level wavelength”). In addition, gₚ(T) is a peak wavelength of a gain (hereinafter referred to as a “gain wavelength”) of an active layer (a multiple quantum well structure). As shown in FIG. 11, the quantum level wavelength λ_{g}(T) shifts to a longer wavelength side as the temperature rises. Also, the gain wavelength gₚ(T) is located on a shorter wavelength side with respect to the quantum level wavelength λ_{g}(T).

In the change in the gain spectrum with temperature shown in FIG. 11, first, a change in the quantum level wavelength with temperature will be described. The quantum level wavelength (μm) is λ_{g}(T)=1.24/E_{g}(T) where E_{g}(T) is the bandgap of the semiconductor (eV). Here, the bandgap E_{g}(T) of the semiconductor is empirically expressed by the Varshni equation in Formula (1).

$$\begin{matrix}[ Math . 1 ] & \\ {E}_{g} ( T ) = {E}_{g} ( T = 0 ) - \frac{α {T}^{2}}{T + β} & ( 1 )\end{matrix}$$

In Formula (1), T is a temperature in units of kelvins, E_{g}(T) is a bandgap at temperature T K, E_{g}(T=0) is the bandgap at temperature 0 K, and α and β are constants determined by a material. α and β of a ternary or higher mixed crystal semiconductor can be obtained by linearly interpolating values of a binary mixed crystal in accordance with a composition ratio.

From Formula (1), a change in the bandgap E_{g}(T) with temperature is determined by α and β, and thus depends on the material. Thus, in order to prevent laser characteristics from changing significantly due to an operating temperature in a semiconductor laser, it is effective to reduce a change in a gain peak wavelength of an active layer with temperature by using a material with a small band gap change due to temperature.

FIG. 12 shows the results of calculating a change in a quantum level wavelength with temperature using Formula (1) for InGaAs and InGaAsP lattice-matched to InP. Two different compositions were used for InGaAsP, with quantum level wavelengths of 1.3 μm and 1.55 μm at room temperature. In both compositions, a change rate of the quantum level wavelength with respect to a change with temperature is 0.5 nm/K or more. This change rate is several times a change rate of the oscillation wavelength of a DFB laser with temperature (up to 0.1 nm/K).

As described above, it is difficult to make the change in the quantum level wavelength with temperature equal to that of a DFB laser using a material such as InGaAs or InGaAsP, which has been traditionally used for growth on InP substrates.

In order to solve this problem, a semiconductor laser using a material containing bismuth, thallium, or the like that can reduce a change in bandgap with temperature is disclosed (for example, NPL 2 and NPL 3). However, since these are new materials, crystal growth is difficult, and it is currently difficult to obtain good laser characteristics.

Next, the change in the gain wavelength gₚ(T) with temperature will be described.

As described above, the gain wavelength gₚ(T) I is located on the shorter wavelength side with respect to the quantum level wavelength λ_{g}(T). As a result, the oscillation wavelength of a Fabry-Perot laser becomes shorter than the quantum level wavelength λ_{g}(T).

Here, the gain wavelength gₚ(T) is located on the shorter wavelength side than the quantum level wavelength λ_{g}(T) because band filling occurs in a conduction band and a valence band. More specifically, in order to produce laser oscillation, carriers (electrons and holes) must be injected into an active layer to obtain a gain sufficient to cancel a loss due to light absorption or the like, and due to this, the Fermi level shifts toward the inside of the band.

With the rise of the operating temperature, light absorption occurs due to Auger recombination, absorption in the valence band, or the like, and thus it is necessary to inject more carriers for laser oscillation than at a lower temperature. As the injected carriers increase, the gain wavelength due to the band filling shifts to a shorter wavelength side.

As described above, with the rise of the temperature, the quantum level wavelength becomes longer, and the gain peak wavelength becomes shorter due to the increase of the injected carriers. Here, since the longer quantum level wavelength is dominant over the shorter gain peak wavelength, the gain peak wavelength becomes longer as a whole as shown in FIG. 11.

Here, when a threshold current density of a semiconductor laser does not change greatly at an operating temperature, carriers injected into the active layer at the start of laser oscillation do not change greatly at the operating temperature. As a result, an interval between the gain peak wavelength and the quantum level wavelength does not change greatly when the temperature changes. In this case, wavelength intervals of gₚ(T₁), gₚ(T₂), and gₚ(T₃) in FIG. 11 are approximately equal to the wavelength intervals of λ_{g}(T₁), λ_{g}(T₂) and λ_{g}(T₃).

### Solution to Problem

In order to solve the above-described problems, a multiple quantum well structure according to embodiments of the present invention is a multiple quantum well structure disposed between a p-type semiconductor and an n-type semiconductor in a semiconductor laser, the multiple quantum well structure including a plurality of well layers and a plurality of barrier layers having shorter composition wavelengths than the plurality of well layers, wherein a quantum level wavelength of at least one of the plurality of well layers, excluding the p-side well layer closest to the p-type semiconductor, is shorter than a quantum level wavelength of the p-side well layer.

Also, a manufacturing method for a multiple quantum well structure according to embodiments of the present invention is a manufacturing method for a multiple quantum well structure used for a semiconductor laser, the method including using an n-type InP substrate to, in order, crystal-grow the multiple quantum well structure including a plurality of InGaAsSb well layers and a plurality of InGaAsSb barrier layers having shorter composition wavelengths than the InGaAsSb well layers, and crystal-grow a p-type InP clad layer, wherein an amount of As supplied and an amount of Sb supplied when each of the InGaAsSb well layers is grown are equal, and an Sb content increases in order from the InGaAsSb well layer closest to the n-type InP substrate to the InGaAsSb well layer closest to the p-type InP clad layer.

### Advantageous Effects

According to embodiments of the present invention, it is possible to provide a multiple quantum well structure, a semiconductor laser, and a manufacturing method for a multiple quantum well structure in which a change in laser characteristics with respect to a change with temperature can be inhibited.

### BRIEF DESCRIPTION OF THE DRAWINGS

FIG. 1A is a schematic diagram showing a configuration of a multiple quantum well structure in a semiconductor laser according to a first embodiment of the present invention.

FIG. 1B is a schematic diagram showing a configuration of a multiple quantum well structure according to a semiconductor laser in the related art.

FIG. 2A is a diagram for illustrating an operation of the multiple quantum well structure according to the semiconductor laser in the related art.

FIG. 2B is a diagram for illustrating an operation of the multiple quantum well structure according to the semiconductor laser in the related art.

FIG. 2C is a diagram for illustrating an operation of the multiple quantum well structure according to the semiconductor laser in the related art.

FIG. 3 is a diagram for illustrating an operation of the multiple quantum well structure according to the semiconductor laser in the related art.

FIG. 4A is a diagram for illustrating an operation of the multiple quantum well structure in the semiconductor laser according to the first embodiment of the present invention.

FIG. 4B is a diagram for illustrating an operation of the multiple quantum well structure in the semiconductor laser according to the first embodiment of the present invention.

FIG. 4C is a diagram for illustrating an operation of the multiple quantum well structure in the semiconductor laser according to the first embodiment of the present invention.

FIG. 5A is a diagram for illustrating an operation of the multiple quantum well structure in the semiconductor laser according to the first embodiment of the present invention.

FIG. 5B is a diagram for illustrating an operation of the multiple quantum well structure in the semiconductor laser according to the first embodiment of the present invention.

FIG. 5C is a diagram for illustrating an operation of the multiple quantum well structure in the semiconductor laser according to the first embodiment of the present invention.

FIG. 6 is a schematic diagram showing a configuration of a semiconductor laser according to a first example of the present invention.

FIG. 7 is a diagram for illustrating an effect of the semiconductor laser according to the first example of the present invention.

FIG. 8 is a diagram for illustrating an effect of the semiconductor laser according to the first example of the present invention.

FIG. 9 is a schematic diagram showing a configuration of a semiconductor laser according to a second example of the present invention.

FIG. 10 is a diagram for illustrating the semiconductor laser in the related art.

FIG. 11 is a diagram for illustrating the semiconductor laser in the related art.

FIG. 12 is a diagram for illustrating the semiconductor laser in the related art.

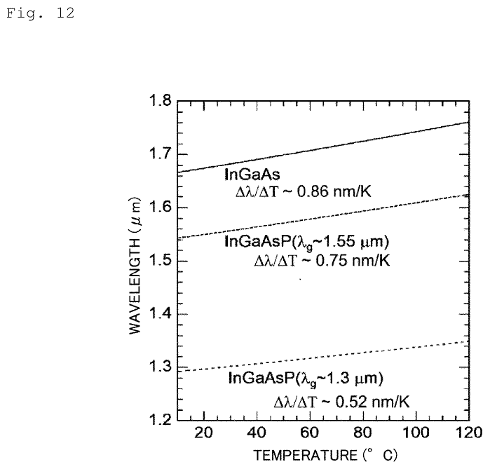

### DETAILED DESCRIPTION OF ILLUSTRATIVE EMBODIMENTS

The present disclosure relates to a multiple quantum well structure, a semiconductor laser, and a manufacturing method for a multiple quantum well structure in which a change in laser characteristics can be inhibited when a temperature changes.

### First Embodiment

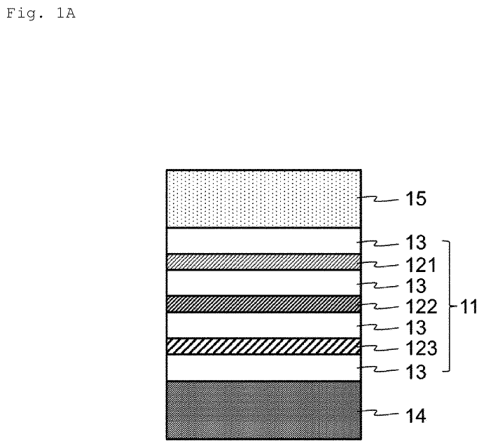

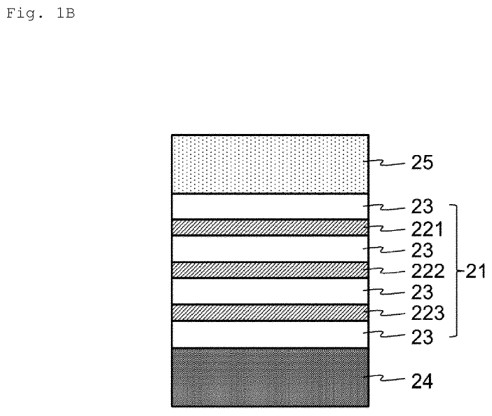

A semiconductor laser according to a first embodiment of the present invention will be described with reference to FIGS. 1A to 5C.

### <Configuration of Semiconductor Laser>

A semiconductor laser 10 according to the present embodiment includes, as an example, a multi-quantum well (MQW) 11 shown in FIG. 1A. The multi-quantum well (MQW) 11 is disposed between an n-type region 14 including an n-type semiconductor and a p-type region 15 including a p-type semiconductor.

The MQW 11 includes three well layers 121 to 123 and four barrier layers 13. Composition wavelengths of the barrier layers 13 are shorter than those of the well layers 121 to 123.

A composition of each of the three well layers 121 to 123 is set so that quantum level wavelengths increase from the well layer (hereinafter also referred to as an “n-side well layer”) 123 closest to the n-type region 14 (n-type semiconductor) to the well layer (hereinafter also referred toward as a “p-side well layer”) 121 closest to the p-type region 15. For example, the three well layers 121 to 123 are made of InGaAsP having different compositions, and thicknesses of the layers are about 6 nm each.

Also, for example, the four barrier layers 13 are made of InGaAsP having the same composition, and thicknesses of each layer are also about 8 nm, which are equal.

For comparison, FIG. 1B shows an example of a multi-quantum well (MQW) in a normal semiconductor laser 20. A multi-quantum well (MQW) 21 is disposed between an n-type region 24 and a p-type region 25, and includes three well layers 221 to 223 and four barrier layers 23, and compositions of the three well layers 221 to 223 are the same. Other configurations are the same as those shown in FIG. 1A.

### <Operations>

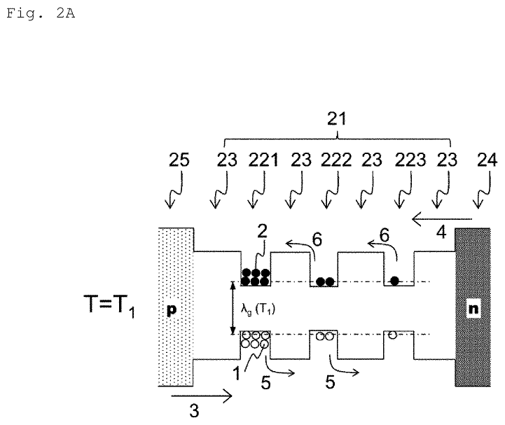

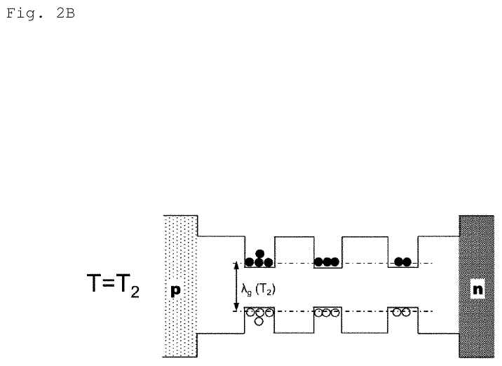

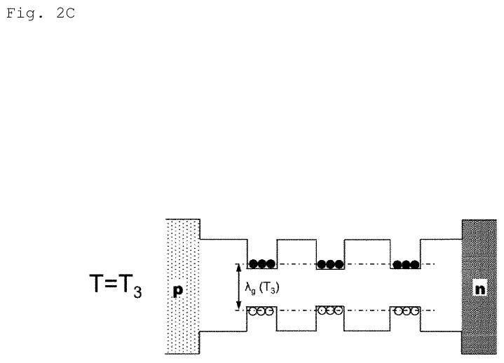

Operations of the semiconductor laser 10 according to the present embodiment will be described with reference to FIGS. 2A to 5C.

First, an operation of the MQW 21 in the normal semiconductor laser 20 will be described from the viewpoint of a distribution of carriers in consideration of movements of carriers among the well layers 221 to 223. Here, although details of the carrier distribution must be analyzed by considering not only band discontinuity but also drift, diffusion, carrier lifetime, and the like, an overview of the distribution of the carriers will be described on the basis of the band discontinuity.

In the MQW 21 of the normal semiconductor laser 20, ideally, if distributions in density of carriers in the well layers 221 to 223 are all the same, the density of carriers required for laser oscillation can be reached at the same time in the well layers 221 to 223, and the semiconductor laser can be operated with good characteristics.

However, since there is the band discontinuity that hinders movements of carriers among the well layers 221 to 223 and the barrier layers 23 in the MQW 21, the carrier distribution in each of the well layers 221 to 223 becomes non-uniform (for example, N. Tessler et al., “Distributed nature of quantum-well lasers,” Appl. Phys. Lett., Vol. 62, No. 10, 1993, 10-12, H. Yamazaki et al., “Evidence of nonuniform carrier distribution in multiple quantum well lasers,” Appl. Phys. Lett., Vol. 71, No. 6, 1997, 767-769, J. Piper et al., “Carrier nonuniformity effects on the internal efficiency of multiquanta-well lasers,” Appl. Phys. Lett., Vol. 74, No. 4, 1999, 489-491, and C. Silvanus et al., “Hole distribution in Ingas 1.3-μm multiple-quantum-well laser structures with different hole confinement energies,” IEEE J. Quantum Electron., Vol. 35, No. 4, 1999, 603-607). This phenomenon is caused by the fact that the effective mass of holes is larger than that of electrons, and thus the holes cannot easily move among the well layers 221 to 223.

FIGS. 2A to 2C schematically show changes in distribution state of holes 1 and electrons 2 in each of the well layers 221 to 223 with respect to changes in operating temperature in the MQW 21 of the normal semiconductor laser 20. Here, operating temperatures are set to T₁<T₂<T₃. Also, quantum level wavelengths λ_{g} of the well layers 221 to 223 are equal. In the figure, dot and dash lines show a ground quantum level on a valence band side and a ground quantum level on a conduction band side of each of the well layers. In addition, in order to simplify the description, the distribution of the carriers in the figure is shown without considering an increase in injected carriers accompanying an increase in operating temperature.

As shown in FIG. 2A, when the operating temperature is low (T=T₁), a non-uniform distribution in the density of carriers occurs in the well layers 221 to 223, and both the holes 1 and the electrons 2 tend to concentrate on the p-side well layer 221.

More specifically, when the band discontinuity of the valence band is large and the operation temperature is low, some of holes (arrow 3 in FIG. 2A) injected from the p-type region side into the p-side well layer 221 move toward the n-side well layer 223 (arrow 5 in FIG. 2A), but there is a high probability that they remain in the p-side well layer 221 without being able to overcome the barrier, and thus a density of holes in the p-side well layer 221 increases.

On the other hand, electrons (arrow 4 in FIG. 2A) injected from the n-type region side into the n-side well layer 223 can move among the well layers 221 to 223 even if the band discontinuity of the conduction band is large, and are electrically attracted to holes (arrow 6 in FIG. 2A). As a result, a density of electrons increases in the well layer 221 in which the density of holes is large.

As shown in FIGS. 2B and 2C, when the operating temperature rises from T₁ to T₂, T₃, the holes 1 are thermally excited, increasing the probability of overcoming the barrier, and as a result, they move from the p-side well layer 221 to the n-side well layer 223. In this case, the electrons 2 move to be attracted to the holes 1. That is, the non-uniform distribution in the density of carriers in the well layers 221 to 223 is improved by the rise of the operating temperature, and the carriers change to be uniform among the well layers 221 to 223.

Thus, when the operating temperature rises, the movements of the holes 1 among the well layers 221 to 223 change as the quantum level wavelength becomes longer and the gain peak wavelength becomes shorter due to the increase of the injected carriers, and the distribution state of the holes 1 and the electrons 2 in each of the well layers 221 to 223 changes.

Here, the change in movements of the carriers between the well layers with temperature includes complex physical phenomena, but basically depends on the probability that the carriers are thermally excited and overcome the band discontinuity between the well layers and the barrier layers.

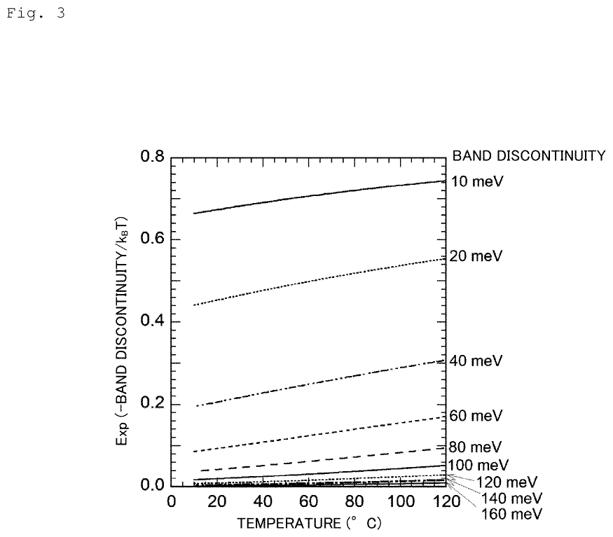

FIG. 3 shows a change with temperature in an index of the probability that the carriers (the holes 1 and the electrons 2) are thermally excited and overcome band discontinuity at an interface with the band discontinuity. The index of the probability the carriers are thermally excited and overcome the band discontinuity is calculated using exp {−[band discontinuity]/(k_{B}·T)}. Here, kB is the Boltzmann constant and Tis the temperature. The index was calculated for the band discontinuity of 10 to 160 meV.

The index of the probability that the carriers are thermally excited and overcome the band discontinuity decreases rapidly as the band discontinuity increases. On the other hand, the index increases with the rise of the temperature regardless of a magnitude of the band discontinuity. This indicates that the carriers can easily move among the well layers 221 to 223 as the temperature rises, and the non-uniform distribution state of the carriers among the well layers 221 to 223 becomes a uniform distribution state.

In addition, this index is significantly reduced when the band discontinuity exceeds 140 meV, and the number of carriers that move beyond a potential barrier decreases. As a result, a threshold current increases, making laser oscillation difficult. For example, when the band discontinuity exceeds 140 meV, it has been reported that a time for the holes 1 to move beyond the potential barrier increases (Silfvenius et al., cited above).

As described above, in the MQW 21 of the semiconductor laser 20, the non-uniform distribution of the carriers occurs in each of the well layers 221 to 223 due to the band discontinuity, and this distribution of the carriers tends to be uniform due to the rise of the temperature.

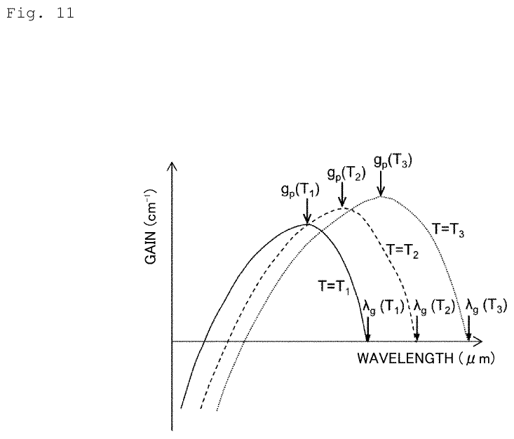

In this case, a change in gain spectrum is substantially the same as that shown in FIG. 11, and a gain peak wavelength becomes longer as the temperature rises. As a result, the oscillation wavelength of the semiconductor laser 20 becomes longer as the operating temperature rises.

Effects of the rise of the temperature on the above-described bandgap and carriers are summarized below.

The quantum level wavelength shifts to a longer wavelength side due to the rise of the temperature in any well layer.

The holes and the electrons tend to concentrate on the p-side well layer when the temperature is low. As the temperature rises, they tend to be injected into the n-side well layer.

The effect of band filling is large in the p-side well layer when the temperature is low. When the temperature rises, the carriers can easily move from the p-side well layer to the n-side well layer, and thus the effect of band filling in the n-side well layer increases.

Next, an operation of the MQW 10 in the semiconductor laser 10 according to the present embodiment will be described.

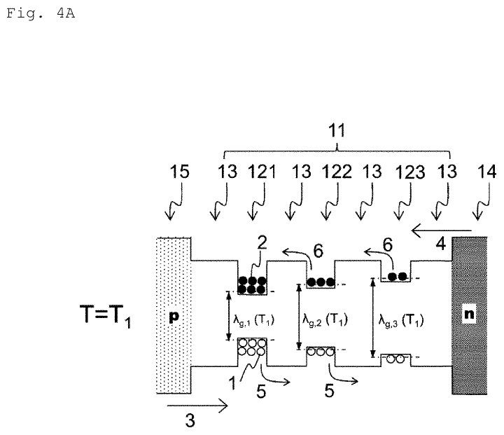

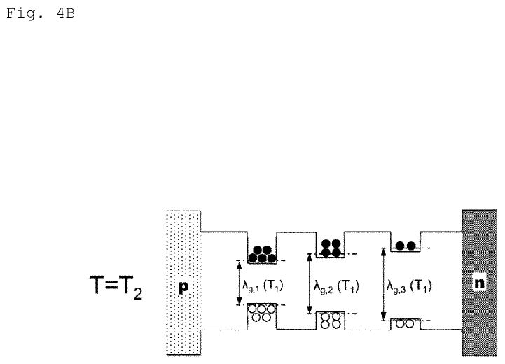

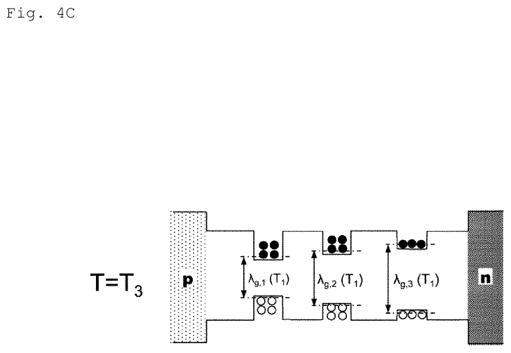

FIGS. 4A to 4C schematically show distribution states of the holes 1 and the electrons 2 at the operating temperatures of T₁, T₂, and T₃ in the MQW 10. Here, the operation temperature is set to T₁<T₂<T₃. Also, the quantum level wavelengths of the well layers 121 to 123 are λ_{g,1}, λ_{g,2}, and λ_{g,3} in order from the p-side well layer 121, and λ_{g1}>λ_{g2}>λ_{g2}>λ_{g3}, regardless of the operating temperature. In the figures, the dot and dash lines indicate the ground quantum level on the valence band side and the ground quantum level on the conduction band side of the well layers. Further, in order to simplify the description, the distribution of the carriers in the figures is shown without considering an increase of injected carriers accompanying an increase of the operating temperature.

As shown in FIG. 4A, when the operating temperature is low (T=T₁), there is a large band discontinuity in the valence band in the p-side well layer 121, which has a long quantum level wavelength, and thus some of holes (arrow 3 in FIG. 4A) injected from the p-type region side move toward the n-side well layer 123 (arrow 5 in FIG. 4A), but there is a high possibility that they remain in the p-side well layer 121 without being able to overcome the barrier, and thus the density of the holes in the p-side well layer 121 becomes higher.

On the other hand, electrons (arrow 4 in FIG. 4A) injected from the n-type region side into the n-side well layer 123 can easily move between the well layers 121 to 123 and are electrically attracted to holes (arrow 6 in FIG. 4A). As a result, the density of electrons increases in the well layer 121 in which the density of holes is large.

In this way, both the holes 1 and the electrons 2 tend to concentrate on the p-side well layer 121, that is, both the holes 1 and the electrons 2 tend to concentrate on the well layer 121 having a longer quantum level wavelength, and a non-uniform distribution in the density of carriers occurs in the well layers 121 to 123.

As shown in FIGS. 4B and 4C, when the operating temperature rises from T₁ to T₂ or T₃, the holes 1 move from the p-side well layer 121 to the n-side well layers 122 and 123, and the electrons 2 also move together with the holes 1. As a result, the non-uniform distribution in the density of carriers in each of the well layers 121 to 123 is improved by the rise of the operating temperature, and the carriers change to be uniform among the well layers 121 to 123. In this way, the number of electrons 2 and holes 1 present in the well layers 122 and 123 having shorter quantum level wavelengths increases.

As described above, when the operating temperature rises, the quantum level wavelength becomes longer and the gain peak wavelength becomes shorter due to the increase of the injected carriers, and movements of the holes 1 among the well layers 121 to 123 change, and the distribution state of the holes 1 and the electrons 2 in each of the well layers 121 to 123 changes. As a result, the carriers present in the well layers having shorter quantum level wavelengths increase due to the increase in operating temperature.

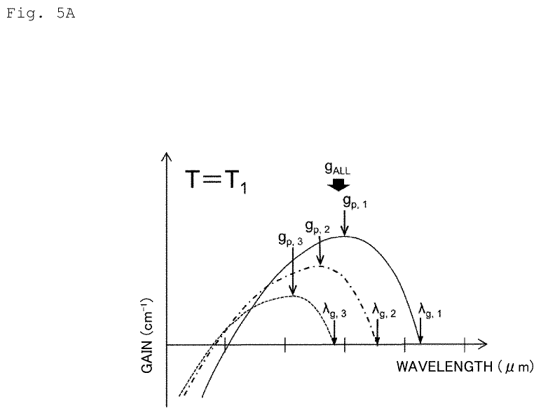

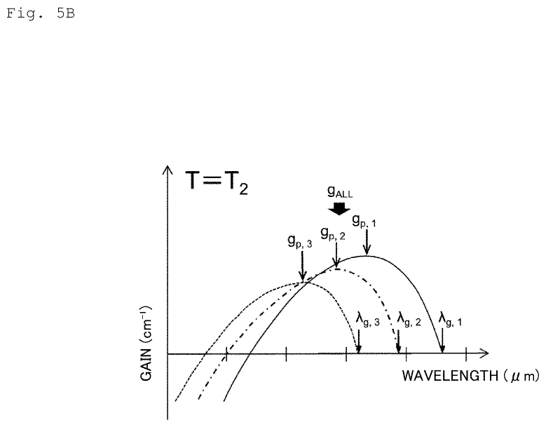

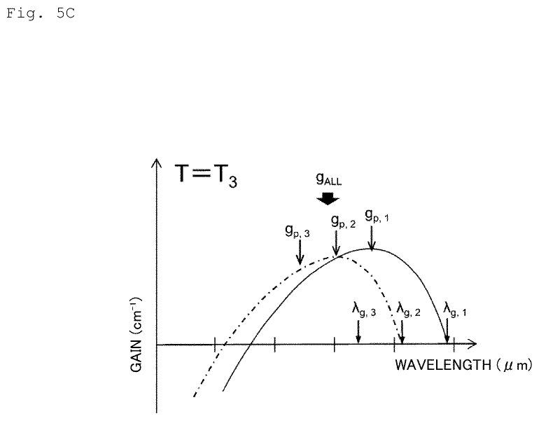

Changes in the gain spectrum of each of the well layers 121 to 123 immediately before oscillation in this case are schematically shown in FIGS. 5A to 5C. In the figures, a positive gain indicates light emission, a negative gain indicates absorption, and a gain of the entire active layer is the sum of gains of the well layers 121 to 123.

When the quantum level wavelengths of the well layers 121 to 123 are defined as λ_{g1}, λ_{g2}, and λ_{g,3} in order from the p-side well layer 121, λ_{g,1}>λ_{g,2}>λ_{g3} are satisfied regardless of the operating temperature. This is because, unless the compositions of the well layers change significantly, α and β in Formula (1) do not change significantly for each well layer. In addition, unless the compositions of the well layers change significantly, the wavelength intervals of λ_{g,1}, λ_{g,2}, and λ_{g,3} do not change significantly, regardless of the operating temperature.

The gain wavelengths of the well layers 121 to 123 are defined as g_{p,1}, g_{p,2}, and g_{p,3} in order from the p-side well layer 121. The gain wavelength varies not only by the operating temperature but also by a density of the injected carriers. The gain of the entire active layer is the sum of the gains of the well layers 121 to 123, and a peak wavelength due to the sum of the gains (hereinafter referred to as the “entire gain wavelength”) is defined as g_{ALL}.

When the operating temperature is low (T=T₁), the density of the carriers in the p-side well layer 121 is high, and thus a ratio of the gain on the p-type region 15 side, that is, the gain of the well layer 121 having a longer quantum level wavelength to the gain of the entire active layer is large. As a result, the entire gain wavelength g_{ALL} becomes close to the gain wavelengths g_{p,1} of the p-side well layer.

When the operating temperature rises (T=T₂ or T₃), the density of the carriers increases not only in the p-side well layer 121 but also in the well layers 122 and 123 close to the n-type region 14, and thus ratios of the gains of the well layers 122 and 123 increases in the gain of the entire active layer. As a result, the entire gain wavelength g_{ALL} shifts from the gain wavelengths g_{p,1} of the p-side well layer 121 toward the gain wavelengths g_{p,2} and g_{p,3} of the well layers 122 and 123 close to the n-type region 14.

As described above, when the temperature rises, the ratios of the gains of the well layers 122 and 123 close to the n-type region 14 to the gain of the entire active layer increase. As a result, the entire gain wavelength g_{ALL} is close to the gain wavelength g_{p,1} of the p-side well layer 121 when the operating temperature is low, and comes closer to the gain wavelengths g_{p,2} and g_{p,3} of the well layers 122 and 123 close to the n-type region 14 when the operating temperature rises.

In the present embodiment, since the quantum level wavelengths of the well layers 122 and 123 close to the n-type region 14 are shorter than the quantum level wavelength of the p-side well layer 121, light emission of the well layers 122 and 123 close to the n-type region 14, that is, light emission at a shorter wavelength increases when the operating temperature rises, and thus the gain wavelength of the entire active layer shifts to a shorter wavelength side, and a shift to a longer wavelength side is inhibited.

Accordingly, according to the semiconductor laser according to the present embodiment, it is possible to inhibit a change in oscillation wavelength when the operating temperature changes, as compared with a semiconductor laser in the related art.

Thus, in the semiconductor laser according to the present embodiment, particularly in a distributed feedback laser, the shift of the gain wavelength to a longer wavelength due to an increase in temperature is inhibited, and thus a difference between the gain wavelength and a desired oscillation wavelength set by a diffraction grating does not increase, and a large gain can be obtained near the oscillation wavelength. As a result, an increase in threshold current and a decrease in efficiency can be inhibited at a high temperature, and good laser characteristics can be obtained.

In the semiconductor laser 10 according to the present embodiment, since the respective well layers 121 to 123 have different gain wavelengths, a peak width of the gain of the entire active layer tends to increase, that is, the gain tends to be distributed over a wide wavelength range. As a result, the gain of the entire active layer is reduced at the desired oscillation wavelength, which may cause deterioration of the laser characteristics, such as an increase in threshold current or a decrease in efficiency (a change rate of an optical output with respect to an injection current).

In order to inhibit the deterioration of the laser characteristics, it is required to make gain peaks from the respective well layers 121 to 123 overlap each other and to increase the gain of the entire active layer at the desired oscillation wavelength. Thus, it is desirable to set the interval between the gain wavelength (gain peak) of the p-side well layer 121 and the gain wavelength (gain peak) of the n-side well layer 123 to be narrower.

On the other hand, when the interval between the gain wavelength (gain peak) of the p-side well layer 121 and the gain wavelength (gain peak) of the n-side well layer 123 is narrowed, the effect of inhibiting a change in wavelength due to a change with temperature is reduced.

Thus, it is desirable to set the interval between the gain wavelength (gain peak) of the p-side well layer 121 and the gain wavelength (gain peak) of the n-side well layer 123 in an appropriate wavelength range.

Here, intervals among the gain wavelengths of the respective well layers 121 to 123 are approximately the same as intervals among the quantum level wavelengths unless extremely uneven distribution of carriers occurs. Thus, by appropriately setting the interval between the quantum level wavelengths of the p-side well layer 121 and the n-side well layer 123, the gains of the respective well layers 121 to 123 can be made to overlap each other, and the gain of the entire active layer can be increased at the desired oscillation wavelength.

In the present embodiment, since the quantum level wavelength differs for each well layer, the interval between the quantum level wavelengths of the p-side well layer 121 and the n-side well layer 123 is greater than 0 nm.

On the other hand, when the interval between the quantum level wavelengths of the p-side well layer 121 and the n-side well layer 123 is too wide, the portion (wavelength range) of each well layer in which the gains overlap decreases, and a well layer which does not contribute to laser oscillation is generated. It depends on shapes of the gain spectra of the respective well layers whether or not the gains of the respective well layers overlap each other. If wavelength ranges of the gains of each well layer (widths of the gain peaks) are 40 nm, a large gain can be maintained (e.g., N. Nonoy et al., “Tunable distributed amplification (TDA-) DFB lasers with asymmetric structure,” IEEE J. Sel. Topics Quantum Electron., Vol. 17, No. 6, 2011, 1505-1512). Thus, if the gain wavelength of the p-side well layer 121 and the gain wavelength of the n-side well layer 123 are in a positive region (light emitting region) within a wavelength range of 40 nm, all the well layers can contribute to laser oscillation.

As described above, unless extremely uneven distribution of carriers occurs, the intervals among the gain wavelengths of the respective well layers are approximately the same as the intervals among the quantum level wavelengths. Thus, by setting the quantum level wavelength of the n-side well layer 123 within a wavelength range of 40 nm from the quantum level wavelength of the p-side well layer 121, the gain peaks from the respective well layers can be made overlap each other at the oscillation wavelength.

In this way, in the MQW in the present embodiment, it is desirable that the interval between the quantum level wavelength of the well layer on the p-type region side and the quantum level wavelength of the well layer on the n-type region side be set to be greater than 0 nm and equal to or less than 40 nm. Thus, the gain peaks from the respective well layers can be made overlap each other at the desired oscillation wavelength, the reduction in gain can be inhibited, and the deterioration of the laser characteristics can be inhibited.

According to the semiconductor laser according to the present embodiment, it is possible to inhibit a change in laser characteristics due to a change with temperature without using a temperature adjusting element such as a Peltier element. Thus, the semiconductor laser can be miniaturized, and a compact and lightweight mobile system in the gas sensing field or the like can be realized.

### First Example

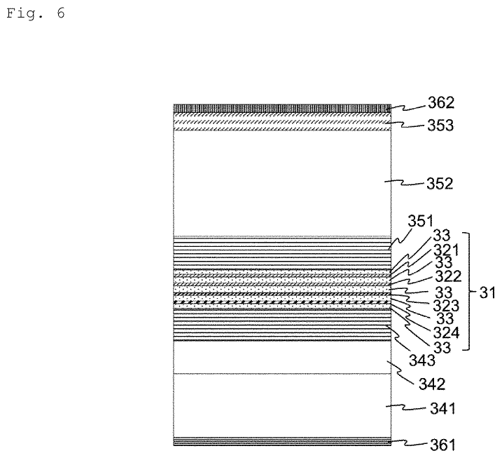

Next, a semiconductor laser according to a first example of the present invention will be described with reference to FIGS. 6 to 8.

### <Configuration of Semiconductor Laser>

A semiconductor laser 30 according to the present example is a Fabry-Perot laser, and includes in order, as shown in FIG. 6, an n-type InP substrate 341, an n-type InP 342, an InGaAsP light confinement layer 343 having a composition wavelength of 1.17 μm, an MQW 31 including four InGaAsSb well layers 321 to 324 and five InGaAsSb barrier layers 33, an InGaAsP light confinement layer 351 having a composition wavelength of 1.17 μm, a p-type InP clad layer 352, and a p-type InGaAs contact layer 353. Further, it includes a p-type electrode 362 on a surface of the p-type InGaAs contact layer 353, and an n-type electrode 361 on a back surface of the InP substrate 341.

### <Manufacturing Method for Semiconductor Laser>

An example of a manufacturing method for the semiconductor laser 30 according to the present example will be described below.

First, using an organometallic molecular beam epitaxy method, in order on the n-type InP substrate 341, the n-type InP 342, the InGaAsP light confinement layer 343 having a composition wavelength of 1.17 μm, the MQW 31 including the four InGaAsSb well layers 321 to 324 and the five InGaAsSb barrier layers 33, the InGaAsP light confinement layer 351 having a composition wavelength of 1.17 μm, and a part of the p-type InP clad layer 352 are grown. At this time, in the growth of the four well layers 321 to 324, a flow rate of a gas for supplying As and a flow rate of a gas for supplying Sb are a₁ and b₁, respectively, and they are equal to each other. Also, In the growth of the five barrier layers 32, a flow rate of the gas for supplying As and a flow rate of the gas for supplying Sb are a₂ and b₂, respectively, and are equal.

Here, in materials containing Sb, Sb undergoes surface segregation during crystal growth and is incorporated into a film growing thereon (for example, O. Pitts et al., “Antimony segregation in GaAs-based multiple quantum well structures,” J. Cryst. Growth, Vol. 254, 2003, 28-34). In the InGaAsSb well layers 321 to 324 in the MQW 31, the effect of surface segregation of Sb becomes larger toward the well layer on the p-type InP clad layer 352 side on the growth surface side (for example, the well layer 321), and a molar composition ratio of Sb in the well layer becomes larger. Due to the change in the molar composition ratio of Sb, a quantum level wavelength of the InGaAsSb well layer on the p-type InP clad layer 352 side (for example, the well layer 321) becomes longer than that of the InGaAsSb well layer on the n-type InP layer 342 side (for example, the well layer 324).

In the case of the MQW 31 in FIG. 6, it is considered that the quantum level wavelength of the InGaAsSb well layer on the p-type InP clad layer 352 side (for example, the well layer 321) is about 10 nm longer than that of the InGaAsSb well layer on the n-type InP layer 342 side (for example, the well layer 324).

Next, on the part of the p-type InP clad layer 352, using an organometallic vapor phase epitaxy method, a remaining part of the p-type InP clad layer 352 and the p-type InGaAs contact layer 353 are grown.

Next, using dry etching and wet etching, the p-type InP clad layer 352 and the p-type InGaAs contact layer 353 are processed into a mesa structure with a stripe width of 2.5 μm.

Next, a silicon oxide film is deposited on a surface of the mesa structure (the p-type InP clad layer 352 and the p-type InGaAs contact layer 353) and on a surface of the InGaAsP light confinement layer 351, and then a silicon oxide film on the p-type InGaAs contact layer 353 is removed.

Next, the p-type electrode 362 is formed on the p-type InGaAs contact layer 353 exposed by removing the silicon oxide film.

Next, after a back surface of the n-type InP substrate 341 is polished, the n-type electrode 361 is formed on the back surface.

Finally, a resonator is formed by cleavage to produce a Fabry-Perot laser having a ridge waveguide structure. Here, a resonator length is 600 μm.

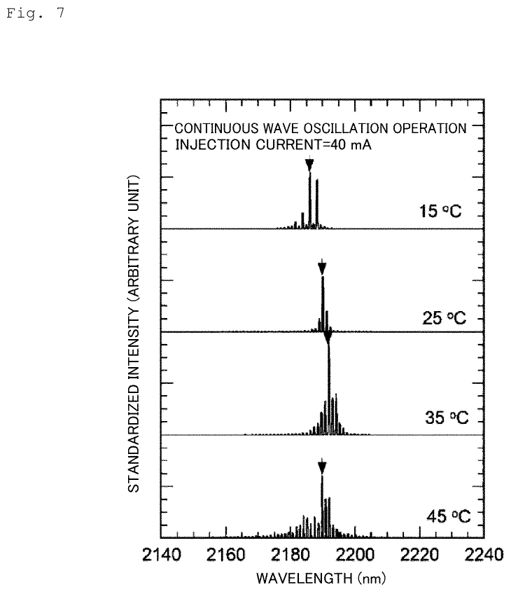

FIG. 7 shows a change in an oscillation spectrum of the semiconductor laser 30 with temperature. The semiconductor laser 30 was operated in continuous oscillation with an injection current of 40 mA. Operating temperatures were 15° C., 25° C., 35° C., and 45° C.

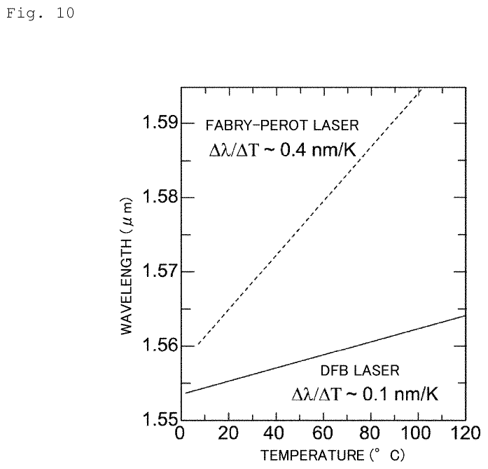

The oscillation wavelength is 2.186 μm at an operating temperature of 15° C. and 2.190 μm at an operating temperature of 45° C., and a change rate of the wavelength due to temperature is 0.13 nm/K. This change rate of the wavelength is a small value that is difficult to achieve with a change rate of a general Fabry-Perot laser (up to 0.4 nm/K) as shown in FIG. 10, and is close to a change rate of a distributed feedback laser (up to 0.1 nm/K).

As described above, in the semiconductor laser 30 according to the present example, the change rate of the oscillation wavelength due to the temperature is small. In this case, in the gain of the entire active layer, at low operating temperatures, the InGaAsSb well layer near the p-type InP clad layer has a large contribution. When the operating temperature rises, the contribution of the InGaAsSb well layer having a shorter quantum level wavelength near the n-type InP layer 342 increases. Thus, the shift of the oscillation wavelength to the longer wavelength side due to the temperature rise is inhibited, and the change rate of the wavelength due to the temperature is reduced.

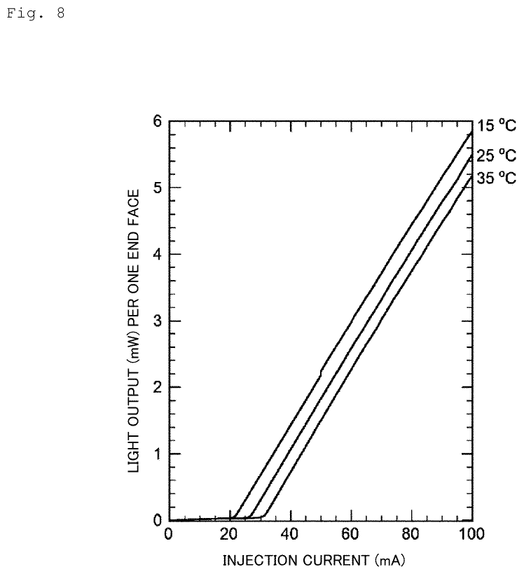

FIG. 8 shows a change in a current-optical output characteristic of the semiconductor laser 30 with temperature. The threshold current is 21 mA at an operating temperature of 15° C. and 31 mA at an operating temperature of 35° C., and an increase in the threshold current due to an increase in operating temperature is inhibited. Also, the efficiency (a change rate of the optical output from both end faces due to injection current) is about 0.08 W/A regardless of the operating temperature, and a decrease in efficiency with an increase in operating temperature is also inhibited. The inhibition of the decrease in efficiency when the operating temperature rises is considered to be due to the fact that the gain peaks overlap between the respective well layers at any operating temperature.

According to the semiconductor laser according to the present example, it is possible to inhibit a change in the oscillation wavelength due to a change with temperature. In addition, the change of the laser characteristics due to a change with temperature can be inhibited, and temperature characteristics of the laser can be improved.

Further, in the present example, an example of a laser using InGaAsSb for the well layers and barrier layers and having an oscillation wavelength exceeding 2 μm has been shown, but the material for the well layers and barrier layers is not limited to InGaAsSb, and the laser is not limited to an oscillation wavelength exceeding 2 μm. Specifically, any material that can be grown on an InP substrate, such as InGaAs, InGaAsP, or AlGaInAs, and whose band gap can be changed by the composition may be used, and the oscillation wavelength may be a wavelength that can be realized on an InP substrate.

In addition, in the present example, an example in which the quantum level wavelength of the InGaAsSb well layer automatically becomes longer for the well layers closer to the p-type region by utilizing the surface segregation of Sb has been shown, but the present invention is not limited thereto, and the composition ratio may be changed by adjusting an amount of raw material supplied. A method of changing the composition ratio by adjusting the amount of raw material supplied is particularly effective when a well layer that does not contain Sb is used. In this case, a device may be manufactured after determining growth conditions of well layers by evaluating compositions of samples individually manufactured (grown) for each well layer having different quantum level wavelengths, or the compositions of the well layers may be evaluated by using secondary ion mass spectrometry or the like after manufacturing the device.

Further, in the present example, an example in which the quantum level wavelengths are changed by changing the compositions of the well layers has been shown, but the present invention is not limited thereto. The quantum level wavelengths of the well layers may be changed by changing layer thicknesses of the well layers. Also, both the compositions and thicknesses of the well layers may be changed. When the thicknesses of the well layers are changed, a binary mixed crystal such as InAs may be used for the well layers.

Further, in the present example, an example in which a Fabry-Perot laser having a ridge waveguide structure is used as the laser structure has been shown, but a buried structure or a distributed feedback laser may be used.

### Second Example

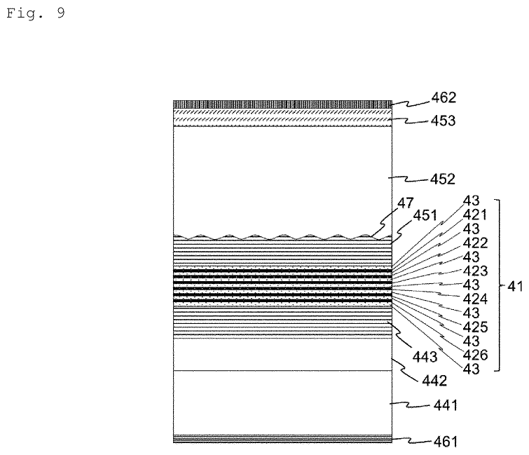

A semiconductor laser according to a second example of the present invention will be described with reference to FIG. 9.

### <Configuration of Semiconductor Laser>

A semiconductor laser 40 according to the present example is a distributed feedback laser, and includes in order, as shown in FIG. 9, an n-type InP substrate 441, an n-type InP 442, an InGaAsP light confinement layer 443 having a composition wavelength of 1.1 μm, an MQW 41 including six InAsP well layers 421 to 426 and seven InGaAsP barrier layers 43, an InGaAsP light confinement layer 451 having a composition wavelength of 1.1 μm, a p-type InP clad layer 452, and a p-type InGaAs contact layer 453. Further, it includes a p-type electrode 462 on a surface of the p-type InGaAs contact layer 453, and an n-type electrode 461 on a back surface of the InP substrate 441. In addition, a diffraction grating 47 is formed between the InGaAsP light confinement layer 451 and the p-type InP clad layer 452.

Thicknesses of the well layers increase in order from the InAsP well layer 426 to the InAsP well layer 421 of the MQW 13. Here, the InAsP well layers 421 to 426 have the same composition.

Also, the seven InGaAsP barrier layers 43 have the same composition and thickness.

### <Manufacturing Method for Semiconductor Laser>

An example of a manufacturing method for the semiconductor laser 40 according to the present example will be described below.

First, using an organometallic vapor phase epitaxy method, in order on the n-type InP substrate 441, the n-type InP 442, the InGaAsP light confinement layer 443 having a composition wavelength of 1.1 μm, the MQW 41 including the six InAsP well layers 421 to 426 and the seven InGaAsP barrier layers 43, the InGaAsP light confinement layer 451 having a composition wavelength of 1.1 μm, and an InP protective layer (not shown) are grown.

Here, the InAsP well layers 421 to 426 included in the MQW 41 are grown by increasing growth times of the well layers stepwise from the InAsP well layer 426 on the n-type InP substrate 441 side to the InAsP well layer 421 on the p-type InP clad layer 452 side, thereby increasing film thicknesses of the InAsP well layers in order from the InAsP well layer 426 to the InAsP well layer 421 as the growth progresses. Thus, as the film thicknesses of the well layers increase, the quantum level wavelengths increase from the InAsP well layer 426 to the InAsP well layer 421 from 1.295 μm to 1.32 μm.

Next, the crystal (wafer) on which the above-mentioned layer structure has been grown is taken out from a growth apparatus, the InP protective layer is removed, and the diffraction grating 47 in which a wavelength of first-order diffracted light is about 1.3 μm is formed on a surface of the InGaAsP light confinement layer 451 by electron beam exposure and wet etching.

Next, the p-type InP clad layer 452 and the p-type InGaAs contact layer 453 are grown on the surface of the InGaAsP light confinement layer 451 on which the diffraction grating 47 is formed by the organometallic vapor phase epitaxy method.

Next, as in the first example, a ridge waveguide structure with a stripe width of 1.5 μm is produced.

Finally, after a resonator is formed by cleavage, a high reflectance film is formed on one end face, and a low reflectance film is formed on the other end face. Here, a resonator length is 300 μm.

In this way, the semiconductor laser (distributed feedback laser) 40 according to the present example is produced.

An oscillation threshold current of the semiconductor laser (distributed feedback laser) 40 according to the present example is 12 mA at an operating temperature of 25° C. and 26 mA at an operating temperature of 85° C., and a characteristic temperature of the threshold current is 79 K.

For comparison, a distributed feedback laser having well layers grown for a specific growth time and provided with an MQW having a quantum level wavelength of 1.31 μm was produced. The configuration other than the well layers is the same as that of the semiconductor laser (distributed feedback laser) 40.

An oscillation threshold current of the semiconductor laser for comparison is 10 mA at an operating temperature of 25° C. and 26 mA at an operating temperature of 85° C., and a characteristic temperature of the threshold current is 64 K.

As described above, in the semiconductor laser (distributed feedback laser) 40, the threshold current at the operating temperature of 25° C. is higher than that of the semiconductor laser for comparison, but it is substantially equal at the operating temperature of 85° C., and the characteristic temperature is also high. This is because the shift of a gain wavelength to a longer wavelength due to an increase in temperature is inhibited in a distributed feedback laser, and thus a difference between the gain wavelength and a desired oscillation wavelength set by a diffraction grating does not increase, and a large gain can be obtained near the oscillation wavelength.

As described above, according to the semiconductor laser according to the present example, it is possible to inhibit a change in gain wavelength due to a change with temperature, and to improve temperature characteristics of the laser.

In the present example, an example in which a distributed feedback laser with a ridge waveguide structure is used for the laser structure has been shown, but a buried structure or a Fabry-Perot laser may also be used.

In the embodiments and examples of the present invention, examples in which the number of well layers in the MQW is 3, 4, or 6 have been shown, but the present invention is not limited thereto, and any number of well layers may be used. Specifically, when the operating temperature range is narrow, the number of well layers may be 2. Alternatively, when the operating temperature range is wide or the band discontinuity of the valence band is large, the number of well layers may be increased. However, there is a high possibility of loss occurring when carriers move beyond a potential barrier, and thus it is not preferable to increase the number of well layers more than necessary. Specifically, the number of well layers is preferably 10 or less, similarly to a laser using a normal MQW.

In the embodiments and examples of the present invention, an example in which the quantum level wavelengths in the MQW increase in order from the n-side well layer to the p-side well layer has been shown, but the present invention is not limited thereto. In the MQW, it is sufficient that the quantum level wavelength of at least one well layer among the well layers excluding the p-side well layer is shorter than the quantum level wavelength of the p-side well layer. For example, in the MQW having eight well layers, the quantum level wavelength of the third well layer from the n-side well layer may be shorter than that of the p-side well layer, and the quantum level wavelength of the other well layers may be equal to that of the p-side well layer.

In the embodiments of the present invention, examples of structures, dimensions, materials, and the like of each constituent part in the configuration, the manufacturing method, and the like of the multiple quantum well structure and the semiconductor laser have been shown, but the present invention is not limited thereto. Any modification that exhibits the functions and effects of the multiple quantum well structure and the manufacturing method of the semiconductor laser may be used.

### INDUSTRIAL APPLICABILITY

The present disclosure relates to a multiple quantum well structure and a semiconductor laser, and can be applied to optical communication systems, gas sensing systems, and the like.

### REFERENCE SIGNS LIST

10 Semiconductor laser
11 Multiple quantum well structure
121, 122, 123 Well layer
13 Barrier layer

1-8. (canceled)

9. A multiple quantum well structure between a p-type semiconductor and an n-type semiconductor in a semiconductor laser, the multiple quantum well structure comprising:
a plurality of well layers; and
a plurality of barrier layers having shorter composition wavelengths than the plurality of well layers,
wherein at least one of the plurality of well layers, excluding a p-side well layer closest to the p-type semiconductor, has a quantum level wavelength shorter than a quantum level wavelength of the p-side well layer.

10. The multiple quantum well structure according to claim 9, wherein an interval of the quantum level wavelengths between the p-side well layer and an n-side well layer closest to the n-type semiconductor is greater than 0 nm and equal to or less than 40 nm.

11. The multiple quantum well structure according to claim 9, wherein compositions or layer thicknesses are different between at least one of the well layers excluding the p-side well layer and the p-side well layer.

12. The multiple quantum well structure according to claim 9, wherein quantum level wavelengths of the plurality of well layers become longer in order from an n-side well layer closest to the n-type semiconductor to the p-side well layer.

13. The multiple quantum well structure according to claim 9, wherein the plurality of well layers comprises InGaAsSb, and an Sb content of each of the plurality of well layers increases in order from an n-side well layer closest to the n-type semiconductor to the p-side well layer.

14. A semiconductor laser comprising:
the multiple quantum well structure according to claim 9.

15. The semiconductor laser according to claim 14, wherein as a temperature rises, a number of holes and electrons present in an n-side well layer closest to the n-type semiconductor increases, and a gain wavelength of the entire multiple quantum well structure shifts to a shorter wavelength side as compared to a gain wavelength of a multiple quantum well structure in which quantum level wavelengths of well layers are equivalent.

16. A manufacturing method for a multiple quantum well structure for a semiconductor laser, comprising:
forming the multiple quantum well structure on an n-type InP substrate, the multiple quantum well structure including a plurality of InGaAsSb well layers and a plurality of InGaAsSb barrier layers having shorter composition wavelengths than the InGaAsSb well layers, by performing crystal growth to form the respective InGaAsSb well layers and the InGaAsSb barrier layers, alternately; and
performing crystal growth of a p-type InP clad layer on the multiple quantum well structure,
wherein:
an amount of As supplied and an amount of Sb supplied when each of the plurality of InGaAsSb well layers is crystal-grown are equal, and
an Sb content increases in order from an InGaAsSb well layer closest to the n-type InP substrate to an InGaAsSb well layer closest to the p-type InP clad layer.

17. The multiple quantum well structure according to claim 10, wherein compositions or layer thicknesses are different between at least one of the well layers excluding the p-side well layer and the p-side well layer.

18. The multiple quantum well structure according to claim 9, wherein the plurality of well layers comprise InGaAsSb, and a molar composition ratio of Sb in each well layer increases from the n-side well layer to the p-side well layer.

19. The multiple quantum well structure according to claim 9, wherein thicknesses of the well layers increase in order from an n-side well layer closest to the n-type semiconductor to the p-side well layer closest to the p-type semiconductor.

20. The semiconductor laser according to claim 14, further comprising a diffraction grating formed between a light confinement layer and the p-type semiconductor.

21. The manufacturing method according to claim 16, wherein crystal growth of the InGaAsSb well layers is performed with equal flow rates of gases for supplying As and Sb.

22. The multiple quantum well structure according to claim 9, wherein the plurality of well layers comprise InAsP, and the quantum level wavelengths of the well layers increase from 1.295 μm to 1.32 μm in order from an n-side well layer closest to the n-type semiconductor to the p-side well layer closest to the p-type semiconductor.

23. The multiple quantum well structure according to claim 9, wherein:
the plurality of well layers comprise six InAsP well layers;
the plurality of barrier layers comprise seven InGaAsP barrier layers;
thicknesses of the six InAsP well layers increase stepwise from an n-side well layer closest to the n-type semiconductor to the p-side well layer closest to the p-type semiconductor;
the seven InGaAsP barrier layers have identical compositions and thicknesses; and
quantum level wavelengths of the six InAsP well layers increase from 1.295 μm for the n-side well layer to 1.32 μm for the p-side well layer.

24. The semiconductor laser according to claim 14, wherein:
the semiconductor laser is a distributed feedback laser;
the multiple quantum well structure is disposed between an n-type InP layer and a p-type InP clad layer;
the multiple quantum well structure comprises six InAsP well layers and seven InGaAsP barrier layers;
a diffraction grating is formed between an InGaAsP light confinement layer and the p-type InP clad layer;
the diffraction grating has a period configured for first-order diffracted light with a wavelength of about 1.3 μm;
the semiconductor laser has a ridge waveguide structure with a stripe width of 1.5 μm and a resonator length of 300 μm;
one end face of the resonator has a high reflectance film and an opposite end face has a low reflectance film;
thicknesses of the six InAsP well layers increase stepwise from an n-side well layer closest to the n-type InP layer to a p-side well layer closest to the p-type InP clad layer; and
quantum level wavelengths of the six InAsP well layers increase from 1.295 μm for the n-side well layer to 1.32 μm for the p-side well layer.
